(19) United States
(12) Patent Application Publication
(10) Pub. No.: US 2009/0194018 A1
(43) Pub. Date: Aug. 6, 2009

(54) APPARATUS AND METHOD FOR MANUFACTURING EPITAXIAL WAFER

(76) Inventors: Shinya HIGASHI, Kanagawa-ken (JP); Hirotaka YANAGISAWA, Kanagawa-ken (JP); Shinichi MITANI, Shizuoka (JP); Hironobu HIRATA, Shizuoka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/354,530

(22) Filed: Jan. 15, 2009

(30) Foreign Application Priority Data
Jan. 16, 2008 (JP) 2008-007448

(51) Int. Cl. C30B 25/10

(52) U.S. Cl. 117/98; 118/725

(57) ABSTRACT

An apparatus for manufacturing an epitaxial wafer, includes: a chamber; a gas inlet provided in the chamber and introducing a reaction gas into the chamber; a gas outlet provided in the chamber and exhausting the reaction gas; a rotator unit provided inside the chamber; a wafer holder provided on an upper portion of the rotator unit and holding a wafer; an inner heater provided inside the rotator unit; and an outer heater provided between the rotator unit and an inner wall of the chamber.

### CROSS-REFERENCE TO RELATED APPLICATIONS

This application is based upon and claims the benefit of priority from the prior Japanese Patent Application No. 2008-007448, filed on Jan. 16, 2008; the entire contents of which are incorporated herein by reference.

### BACKGROUND OF THE INVENTION

1. Field of the Invention

This invention relates to an apparatus and a method for manufacturing an epitaxial wafer.

2. Background Art

In epitaxial growth of vapor-growing a single crystal film on a semiconductor substrate such as a silicon wafer, a CVD (Chemical Vapor Deposition) method is often used. As described in, for example, Patent document 1 (JP-A 2007-19350 (Kokai)), an apparatus for manufacturing an epitaxial wafer using the CVD method has a rotator unit in a chamber, an annular wafer holder holding a wafer on an upper surface of the rotator unit, and an inner heater for heating a wafer below the wafer holder. And, a reaction gas is introduced into the chamber, and a single crystal film is formed on the wafer while rotating the wafer with the rotator unit. In this case, radiation heat from the inner heater increases the temperature of the wafer to a high temperature which is, for example, about 1100° C. At this time, the temperature of the wafer holder also increases.

Because flow velocity of the reaction gas is high in the peripheral portion of the wafer holder, the peripheral portion of the wafer holder is cooled by the reaction gas. Moreover, by radiation to the outer wall cooled with cooling water, the peripheral portion of the wafer holder is cooled. Therefore, the temperature of the peripheral portion of the wafer holder decreases significantly compared with the inner side thereof. The temperature difference between the peripheral portion and the inner side thereof easily causes large stress in the wafer holder. By lowering programming rate of heating with the inner heater, the temperature difference can be reduced and the stress can be relaxed, but this leads to lowering the through-put, and as a result, there has been a bad effect in improvement of productivity. Moreover, when a susceptor holding the back surface of the wafer is used as the wafer holder, the temperature decrease of the peripheral portion of the susceptor, all the same, causes the stress due to the temperature difference in the susceptor. Therefore, a slight strain is caused in the susceptor, and the contact between the back surface of the wafer and the susceptor becomes nonuniform, and as a result, the temperature of the wafer becomes nonuniform, and it has been difficult to obtain a uniform epitaxial film.

Moreover, in general, the temperature of the peripheral portion of the wafer decreases compared with the inner side thereof. By contrast, there is a technique dividing the inner heater into an in-heater (disc-like heater of the central portion) and an out-heater (annular heater provided in the peripheral portion of the in-heater) and setting the temperature of the out-heater higher than that of the in-heater and thereby setting the temperature distribution of the wafer uniformly. However, in this case, the temperature of the out-heater becomes very high, and hence, the operating life of the out-heater shortens, and as a result, lowering of the productivity is caused.

### SUMMARY OF THE INVENTION

According to an aspect of the invention, there is provided an apparatus for manufacturing an epitaxial wafer, including: a chamber; a gas inlet provided in the chamber and introducing a reaction gas into the chamber; a gas outlet provided in the chamber and exhausting the reaction gas; a rotator unit provided inside the chamber; a wafer holder provided on an upper portion of the rotator unit and holding a wafer; an inner heater provided inside the rotator unit; and an outer heater provided between the rotator unit and an inner wall of the chamber.

According to another aspect of the invention, there is provided a method for manufacturing an epitaxial wafer, including: placing a wafer on a wafer holder disposed on an upper portion of a rotator unit provided inside a chamber; heating the wafer by an inner-heater provided inside the rotator unit and an outer-heater provided between the rotator unit and an inner wall of the chamber; introducing a reaction gas into the chamber; and forming an epitaxial film on the wafer while rotating the wafer by the rotator unit.

### BRIEF DESCRIPTION OF THE DRAWINGS

FIG. 1 is a schematic cross-sectional view illustrating the configuration of an apparatus for manufacturing an epitaxial wafer according to a first embodiment of the invention;

FIG. 2 is a view illustrating simulation analysis results on temperature distributions of annular holders of a first embodiment and a comparative example;

FIG. 3 is a view illustrating simulation analysis results on stress distributions of the annular holders of the first embodiment and the comparative example;

FIG. 4 is a view illustrating simulation analysis results on temperature distributions of out-heaters of the first embodiment and the comparative example;

FIG. 5 is a schematic cross-sectional view illustrating the configuration of an apparatus for manufacturing an epitaxial wafer according to a second embodiment of the invention;

FIG. 6 is a schematic cross-sectional view illustrating the configuration of an apparatus for manufacturing an epitaxial wafer according to a third embodiment of the invention;

FIG. 7 is a schematic cross-sectional view illustrating the configuration of an apparatus for manufacturing an epitaxial wafer according to a fourth embodiment of the invention;

FIG. 8 is a schematic cross-sectional view illustrating the configuration of an apparatus for manufacturing an epitaxial wafer according to a fifth embodiment of the invention;

FIG. 9 is a schematic cross-sectional view illustrating the configuration of an apparatus for manufacturing an epitaxial wafer according to a sixth embodiment of the invention; and

FIG. 10 is a flow chart illustrating a method for manufacturing an epitaxial wafer according to a seventh embodiment of the invention.

### DETAILED DESCRIPTION OF THE INVENTION

Hereinafter, embodiments of the invention will be described in detail with reference to drawings.

### First Embodiment

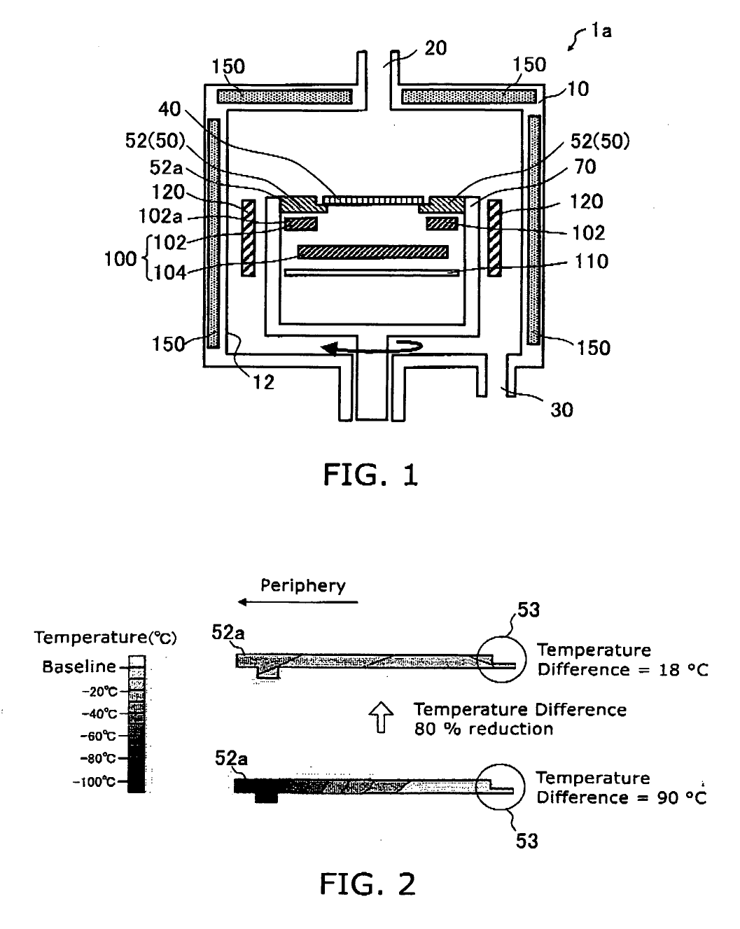

FIG. 1 is a schematic cross-sectional view illustrating the configuration of an apparatus for manufacturing an epitaxial wafer according to a first embodiment of the invention.

As shown in FIG. 1, the apparatus 1a for manufacturing an epitaxial wafer according to the first embodiment has a chamber (treatment furnace) 10. Inside the chamber 10, a rotator unit 70 is provided, and on an upper surface thereof, a wafer holder 50 holding a wafer 40 is provided. FIG. 1 shows an example in which an annular holder 52 holding the peripheral portion of the wafer 40 is provided as the wafer holder 50. The annular holder 52 has an annular shape such as ring shape by the plan view (when viewed from above to below in parallel to the page space in FIG. 1). By the annular holder 52 (wafer holder 50), the wafer is held, and the wafer 40 rotates by the rotator unit 70.

Inside the rotator unit 70, an inner heater 100 heating the wafer 40 is provided. In this embodiment, the inner heater 100 has a disc-like in-heater 104 and an annular out-heater 102 provided on a side of the wafer holder 50 of the inner-heater 104.

And, between the rotator unit 70 and an inner wall 12 of the chamber 10, an outer heater 120 is provided. The outer heater 120 is illustratively based on a structure in which graphite is sandwiched between quartz layers or a resistance-heating heater made of SiC.

Moreover, the chamber 10 is provided with a gas inlet 20 for introducing a reaction gas into the chamber and a gas outlet 30 for exhausting the reaction gas. Moreover, on the outer wall of the chamber 10, a circulation pipe 150 for circulating a coolant for cooling (such as cooling water) is provided.

In the apparatus for manufacturing an epitaxial wafer having such a configuration, the reaction gas, for example, a mixed gas composed of SiH₂Cl₂, which is a source gas, and H₂, which is a carrier gas, is introduced from the gas inlet 20, and while rotating the wafer 40 with the rotator unit 70, an epitaxial film is formed on the wafer 40 held at a high temperature.

The apparatus 1a for manufacturing an epitaxial wafer according to the first embodiment has the outer heater 120, and hence, the peripheral portion of the wafer holder 50 (annular holder 52) can be heated by the outer heater 120. Therefore, a decrease in temperature of the peripheral portion of the annular holder 52 is suppressed, and as a result, the stress of the annular holder 52 can be relaxed. Moreover, by both of the outer heater 120 and the out-heater 102, the peripheral portion of the wafer 40 can be heated, and therefore, the peripheral portion of the wafer 40 can be locally heated, and the temperature distribution of the wafer 40 is uniformized and the temperature of the out-heater 102 can be lowered more than a conventional technique.

### Comparative Example

Hereinafter, an apparatus for manufacturing an epitaxial wafer of a comparative example will be described.

The apparatus for manufacturing an epitaxial wafer of comparative example has the same configuration as the apparatus 1a for manufacturing an epitaxial wafer illustrated in FIG. 1 except that the outer heater 120 is not provided. Because the apparatus for manufacturing an epitaxial wafer of the comparative example does not have the outer heater, the peripheral portion of the annular holder 52 (wafer holder 50) is cooled by a reaction gas, and also, cooled by radiation to the outer wall of the chamber cooled with cooling water. Therefore, the temperature of the peripheral portion decreases compared with the inner side portion of the holder 52, and because of the temperature difference, large stress is caused by the annual holder 52, and the risk that the annular holder 52 is damaged by the stress increases. Moreover, lowering the programming rate of heating by the inner heater 100 for reducing the risk of the damage reduces through-put, and as a result, reduction of productivity is caused.

Moreover, because the peripheral portion of the wafer 40 is heated only by the out-heater 102, the setting temperature of the out-heater 102 has to be considerably high in order to heat the entirety of the wafer 40 to a predetermined temperature or more. Therefore, the operating life of the out-heater 102 shortens, and as a result, this leads to rising of the component cost and lowering of the apparatus availability, and the productivity is lowered.

The present inventors have performed simulation analysis with respect to heat transmission and heat stress for the apparatus for manufacturing an epitaxial wafer of the first embodiment and the above comparative example. That is, in the case of the first embodiment, the outer heater 120 has been set to be 1300° C., and the outputs of the inner heater 100 (in-heater 104 and out-heater 102) and the outer heater 120 have been adjusted so that the temperature of the wafer 40 becomes 1100° C., which is constant. And, temperature distribution and stress distribution of the annular holder 52 and the temperature distribution of the out-heater 102 have been obtained.

In the comparative example, the output of the inner heater 100 (in-heater 104 and out-heater 102) has been adjusted so that the temperature of the wafer 40 becomes 1100° C., which is constant. Similarly, temperature distribution and stress distribution of the annular holder 52 and the temperature distribution of the out-heater 102 have been obtained.

FIG. 2 is a view illustrating simulation analysis results on temperature distributions of the annular holders of the first embodiment and the comparative example.

FIG. 2 shows the temperature distribution in the section of part of the annular holder 52, namely, a left side portion 52a of the annular holder 52 shown in FIG. 1. Light hatching represents high temperature and dark hatching represents low temperature and middle thereof represents middle temperature. The view of the upper stage of FIG. 2 represents the result of this embodiment, and the view of the lower stage represents the result of the comparative example.

As shown in the lower stage of FIG. 2, in the annular holder 52a of the comparative example, the temperature is high in the inner circumferential portion (wafer-holding position 53, right part in the figure) and the temperature is low in the outer peripheral portion (left part in the figure), and the temperature difference between the inner circumferential portion and the outer peripheral portion was 90° C. This is because the annular holder 52 rotates at high speed with the rotator unit 70, and in particular, flow velocity of the reaction gas is high in the outer peripheral portion of the annular holder 52, and therefore, the peripheral portion of the annular holder 52 is cooled by the gas and also cooled by radiation to the outer wall of the chamber 10.

By contrast, as shown in the upper stage of the FIG. 2, in the annular holder 52a of the first embodiment, the temperature in the inner circumferential portion is high and approximately the same as the comparative example, and there is little decrease in temperature of the outer peripheral portion, and the temperature difference between the inner circumferential portion and the outer peripheral portion was 18° C. That is, the temperature difference is reduced by 80% in this embodiment, with respect to the comparative example. As described above, in the apparatus 1a for manufacturing an epitaxial wafer according to the first embodiment, the temperature difference in the annular holder 52 (wafer holder 50) can be reduced.

Next, the results of simulation analysis with respect to heat stress of the annular holders will be described.

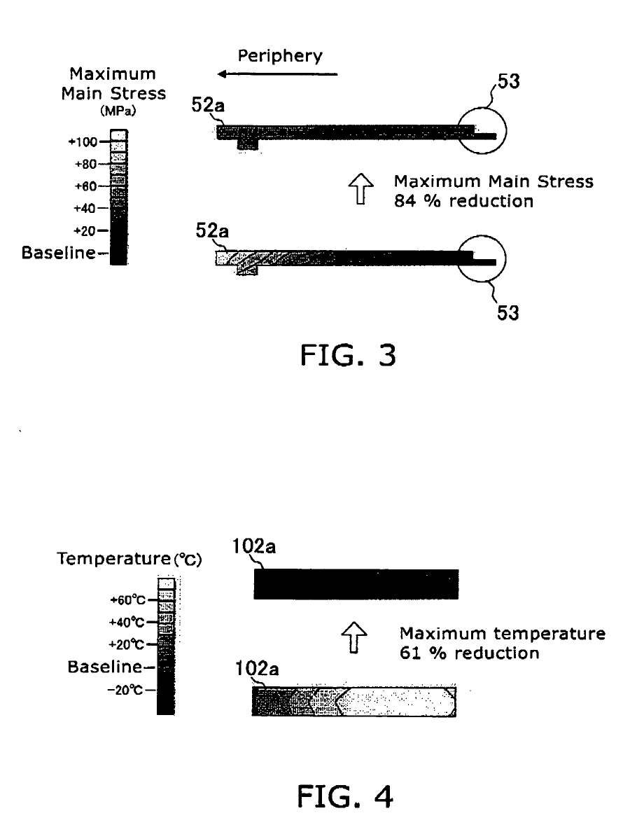

FIG. 3 is a view illustrating simulation analysis results on stress distributions of the annular holders of the first embodiment and the comparative example.

FIG. 3 shows the distribution of maximum main stress of the section of the left side portion 52a of the annular holder 52. Light hatching represents that the maximum main stress is large and dark hatching represents that the maximum main stress is small and middle thereof represents the middle maximum main stress. Moreover, the view of the upper stage of FIG. 3 shows the result of this embodiment and the view of the lower stage shows the result of the comparative example.

As shown in the lower stage of FIG. 3, in the annular holder 52a of the comparative example, the maximum main stress is small in the inner circumferential portion (right part in the figure) and the maximum main stress is large in the outer peripheral portion (left part in the figure). And, the difference of the maximum main stress between the inner circumferential portion and the outer peripheral portion is large.

By contrast, as shown in the upper stage of FIG. 3, in the annular holder 52a of the first embodiment, the maximum main stress is small in both of the inner circumferential portion and the outer peripheral portion, and the difference therebetween is also small. The maximum value of the maximum main stress is reduced by 84% in the first embodiment, with respect to the maximum value of the maximum main stress of the comparative example. This is because in the first embodiment, there is little decrease in temperature in the outer peripheral portion and the temperature difference between the inner circumferential portion and the outer peripheral portion is reduced by 80% with respect to the comparative example as described in FIG. 2, and the improvement ratios of the results also accord with each other very much.

As described above, the apparatus 1a for manufacturing an epitaxial wafer according to the first embodiment reduces the temperature difference in the annular holder 52, and as a result, the stress and the stress distribution in the annular holder 52 can be significantly relaxed.

Next, the results of simulation analysis with respect to the temperature of the out-heater 102 will be described.

FIG. 4 is a view illustrating simulation analysis results on temperature distributions of the out-heaters of the first embodiment and the comparative example.

FIG. 4 shows the temperature distribution of the section of part of the out-heater 102, namely the left side portion 102a of the out-heater 102 shown in FIG. 1. Light hatching represents high temperature and dark hatching represents low temperature and middle thereof represents middle temperature. Moreover, the view of the upper stage of FIG. 4 represents the result of this embodiment, and the view of the lower stage of FIG. 4 represents the result of the comparative example.

As shown in FIG. 4, in order to heat the temperature of the wafer 40 to be 1100° C., it is necessary to set the temperature of the out-heater 102a of the comparative example (view of the lower stage) at a very high temperature, but in the first embodiment (view of the upper stage), the temperature of the out-heater 102a can be set to be low. By comparing both of the cases, the maximum temperature of the out-heater 102a of this embodiment can be lower than the maximum temperature of the comparative example by 61° C.

As described above, the apparatus 1a for manufacturing an epitaxial wafer according to the first embodiment can heat the outer peripheral portion of the wafer 40 by both of the outer heater 120 and the out-heater 102, and hence, the temperature of the out-heater 102 can be lowered. Moreover, the precise temperature adjustment by the outer heater 120 can be performed independently from the inner heater (out-heater 102 and in-heater 104), and hence, the uniformity of the temperature of the wafer 40 can also be improved.

As described above, the apparatus 1a for manufacturing an epitaxial wafer according to the first embodiment reduces the temperature difference in the annular holder 52 (wafer holder 50), and thereby, the stress is relaxed to lower damaging risk or strain of the annular holder 52 (wafer holder 50), and also, by lowering the temperature of the out-heater 102, the out-heater 102 can be made long-lived, and temperature uniformity of the wafer 40 can be improved. Thus, this can provide the manufacturing apparatus and the manufacturing method for an epitaxial wafer with high productivity by which a uniform epitaxial film can be obtained.

In the first embodiment, the disposition of the outer heater 120 is optional as long as the outer heater 120 is located between the rotator unit 70 and the inner wall 12 of the chamber 10. However, in order not to adversely affect the flow velocity of the reaction gas, the upper surface of the outer heater 120 can be set at substantially the same position as the upper surface of the rotator unit 70 or below the upper surface thereof.

FIG. 1 illustrates the configuration in which the in-heater 104 and the annular out-heater 102 are provided below the annular holder 52, but the invention is not limited thereto, and as described later, the in-heater 104 and the out-heater 102 may be in substantially the same plane position, or a disc-like heater integrating the in-heater 104 and the out-heater 102 is also possible.

Moreover, in this embodiment, below the inner heater 100, a shielding plate 110 for more efficient heating is provided. The shielding plate 110 can be illustratively based on silicon, SiC, quartz, graphite coated with quartz, and so forth. In the embodiment of the invention, the shielding plate 110 is not necessarily provided, and the shielding plate is provided as needed.

### Second Embodiment

Next, a second embodiment of the invention will be described.

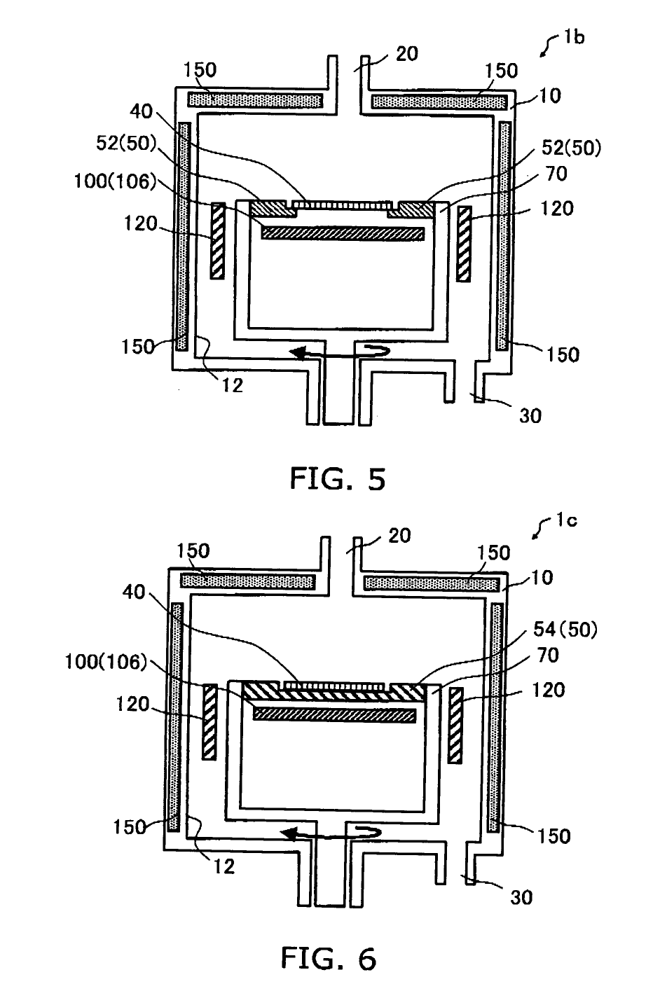

FIG. 5 is a schematic cross-sectional view illustrating the configuration of an apparatus for manufacturing an epitaxial wafer according to a second embodiment of the invention.

As shown in FIG. 5, in the apparatus 1b for manufacturing an epitaxial wafer according to the second embodiment, the inner heater 100 is not divided into the in-heater 104 and the out-heater 102 (see, FIG. 1), and is composed of an integrated disc-like heater 106. In the specific example shown in FIG. 5, the shielding plate 110 is not provided but the shielding plate 110 may be provided.

Also, in the apparatus 1b for manufacturing an epitaxial wafer according to the second embodiment, in addition to the inner heater 100 (disc-like heater 106), the outer heater 120 is provided, and hence, the temperature difference in the annular holder 52 is small, and thus, the risk of damaging the annular holder 52 can be reduced. Thereby, the programmable rate of heating by the inner heater 100 and the outer heater 120 can be increased, and hence, through-put can be improved.

Moreover, when the disc-like heater 106 has a configuration of being capable of independently controlling the temperatures of the peripheral portion and the inner side portion, the temperature of the peripheral portion is set to be higher than that of the inner side portion. In this case, the peripheral portion can be heated by the outer heater 120, and hence, the temperature of the peripheral portion of the disc-like heater 106 can be set low. Thereby, the disc-like heater 106 can be made long-lived. Moreover, when the disc-like heater 106 cannot independently control the temperatures of the peripheral portion and the inner side portion, in general, the temperature of the peripheral portion is lower than that of the inner side portion, and hence, the temperature of the wafer 40 becomes nonuniform. By contrast, in this embodiment, because the outer heater 120 is provided, the peripheral portion of the wafer 40 can be heated, and as a result, the temperature of the wafer 40 can be made uniform, and thereby, an epitaxial wafer of high quality can be obtained.

As described above, the apparatus 1b for manufacturing an epitaxial wafer according to the second embodiment reduces the temperature difference in the annular holder 52, the stress is relaxed to reduce damaging risk or strain of the annular holder 52, and by lowering the temperature of the peripheral portion of the disc-like heater 106, the disc-like heater 106 can be made long-lived, and temperature uniformity of the wafer 40 can be improved. Thus, this can provide the manufacturing apparatus and the manufacturing method for an epitaxial wafer with high productivity by which a uniform epitaxial film can be obtained.

### Third Embodiment

Next, a third embodiment of the invention will be described.

FIG. 6 is a schematic cross-sectional view illustrating the configuration of an apparatus for manufacturing an epitaxial wafer according to a third embodiment of the invention.

As shown in FIG. 6, the apparatus 1c for manufacturing an epitaxial wafer according to the third embodiment has a susceptor 54 as the wafer holder 50 instead of the annular holder 52.

The susceptor 54 holds the wafer 40, for example, so as to be in contact with the entire back surface of the wafer 40 or holds the peripheral portion of the wafer 40 so as to have a slight void between the back surface of the wafer 40 and the susceptor 54, and has a function of uniformizing the temperature of the wafer 40 by the heat conduction in the plane direction of the susceptor.

By the reaction gas and the radiation to the outer wall of the chamber 10, the temperature of the peripheral portion of the susceptor 54 decreases more than the inner side portion thereof. Thereby, the stress in the susceptor 54 is caused and the risk of damaging susceptor 54 increases. Furthermore, by the stress, strain is caused in the susceptor 54, and the contact condition between the susceptor 54 and the wafer 40 or the distance of the void therebetween becomes nonuniform, and thereby, the heat conduction between the susceptor 54 and the wafer 40 is made nonuniform. As a result, occasionally, uniformity of the temperature of the wafer 40 is reduced.

By contrast, in the apparatus 1c of manufacturing an epitaxial wafer according to the third embodiment, the peripheral portion of the susceptor 54 can be locally heated by the outer heater 120, and hence, the temperature of the susceptor 54 can be made uniform. Thereby, damaging risk and strain of the susceptor 54 can be reduced and the operating life thereof can be improved and the contact condition between the susceptor 54 and the wafer 40 can be made uniform, and the temperature of the wafer 40 can be made uniform.

Moreover, the elongation of operating life for the disc-like heater 106 or the uniformization of the temperature of the wafer 40 is the same as described in the second embodiment.

As described above, the apparatus 1c for manufacturing an epitaxial wafer according to the third embodiment can reduce the temperature difference in the wafer holder 50 (susceptor 54) to improve the operating life of the wafer holder 50 (susceptor 54), and the temperature of the peripheral portion of the disc-like heater 106 can be lowered to make the disc-like heater long-lived, and furthermore, the temperature uniformity of the wafer 40 can be improved. Thus, this can provide the manufacturing apparatus and the manufacturing method for an epitaxial wafer with high productivity by which a uniform epitaxial film can be obtained.

### Fourth Embodiment

Next, a fourth embodiment of the invention will be described.

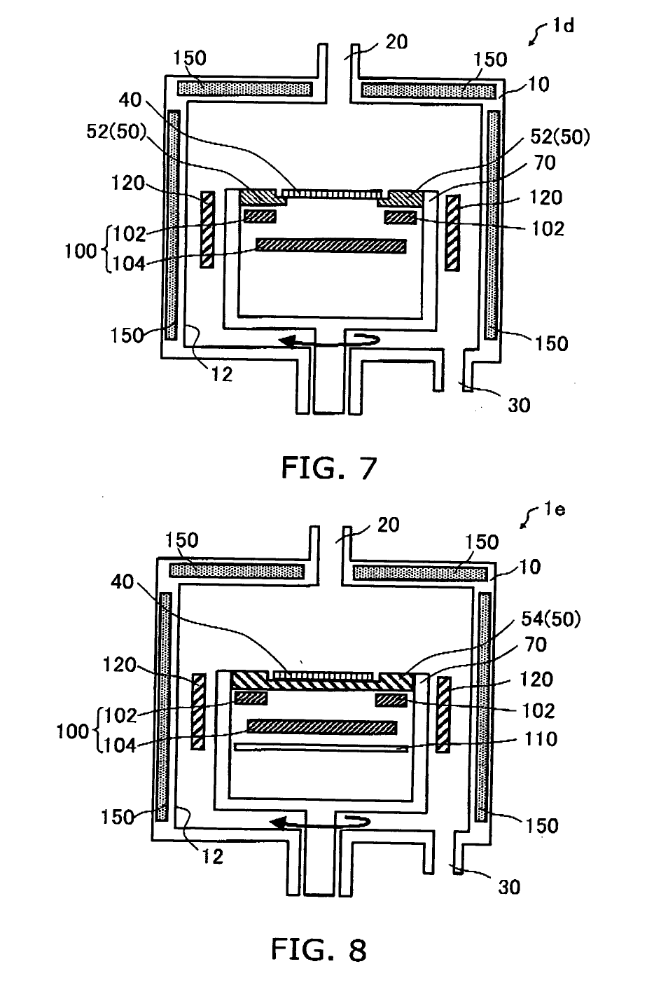

FIG. 7 is a schematic cross-sectional view illustrating the configuration of an apparatus for manufacturing an epitaxial wafer according to a fourth embodiment of the invention.

As shown in FIG. 7, the apparatus 1d for manufacturing an epitaxial wafer according to the fourth embodiment has the configuration in which the shielding plate 110 is omitted in the structure illustrated in FIG. 1.

The shielding plate 110 has a function of improving efficiency of the inner heater 100.

The apparatus 1d for manufacturing an epitaxial wafer according to the fourth embodiment has the outer heater 120. Therefore, the output of the outer heater 120 can be controlled independently from the inner heater 100. Thereby, the temperature of the wafer 40 can be uniformized.

Reduction of temperature difference in the annular holder 52, lowering of damaging risk, and lowering of the temperature and the effect of elongation of the operation life of the out-heater 102 are the same as described in the first embodiment.

As described above, the apparatus 1d of manufacturing an epitaxial wafer according to the fourth embodiment reduces the temperature difference in the wafer holder 50, and thereby, the stress is relaxed to lower damaging risk or strain of the wafer holder 50, and also, by lowering the temperature of the out-heater 102, the out-heater 102 can be made long-lived, and furthermore, even if there is not the shielding plate 110, temperature uniformity of the wafer 40 can be improved. Thus, this can provide the manufacturing apparatus and the manufacturing method of an epitaxial wafer with high productivity by which a uniform epitaxial film can be obtained.

### Fifth Embodiment

Next, a fifth embodiment of the invention will be described.

FIG. 8 is a schematic cross-sectional view illustrating the configuration of an apparatus for manufacturing an epitaxial wafer according to a fifth embodiment of the invention.

As shown in FIG. 8, the apparatus 1e for manufacturing an epitaxial wafer according to the fifth embodiment has the configuration in which the susceptor 54 is used as the wafer holder 50 instead of the annular holder 52 in the structure illustrated in FIG. 1.

Similarly to the third embodiment, in the apparatus 1e for manufacturing an epitaxial wafer according to the fifth embodiment, the temperature difference in the susceptor 54 can be reduced and the strain by the temperature difference can be suppressed, and the contact with the wafer 40 can be made uniform.

As described above, the apparatus 1e for manufacturing an epitaxial wafer according to the fifth embodiment can reduce the temperature difference in the wafer holder 50 (susceptor 54) to relax the stress and thereby damaging risk or strain of the wafer holder 50 (susceptor 54) is reduced, and also, by lowering the temperature of the out-heater 102, the out-heater 102 can be made long-lived, and temperature uniformity of the wafer 40 can be improved. Thus, this can provide the manufacturing apparatus and the manufacturing method for an epitaxial wafer with high productivity by which a uniform epitaxial film can be obtained.

### Sixth Embodiment

Next, a sixth embodiment of the invention will be described.

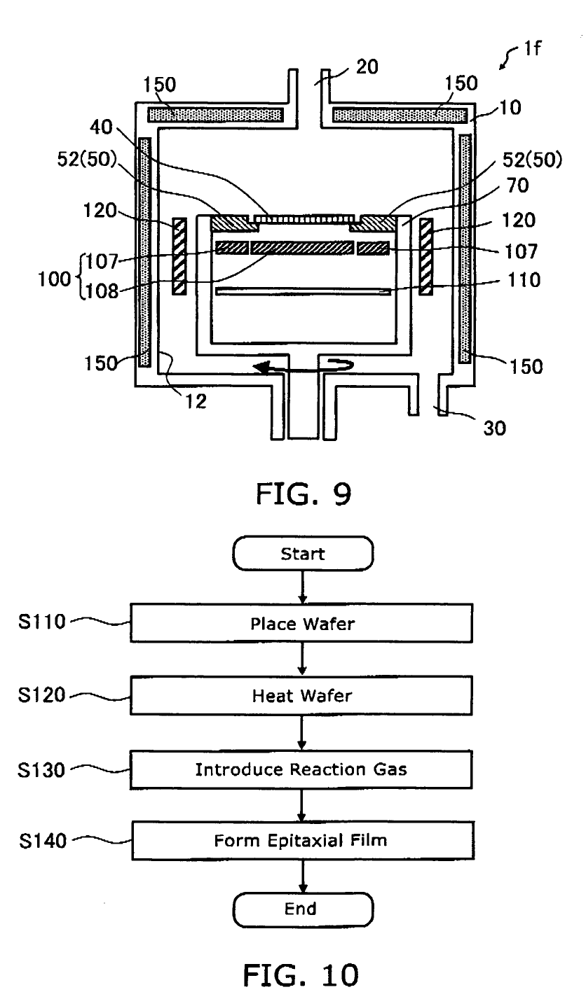

FIG. 9 is a schematic cross-sectional view illustrating the configuration of an apparatus for manufacturing an epitaxial wafer according to a sixth embodiment of the invention.

As shown in FIG. 9, the apparatus if for manufacturing an epitaxial wafer according to the sixth embodiment has the configuration in which an in-heater 108 and an out-heater 107 disposed in substantially the same plane are used as the inner heater 100 in the structure illustrated in FIG. 1.

Because the apparatus 1f for manufacturing an epitaxial wafer according to the sixth embodiment also has the outer heater 120, the temperature of the out-heater 107 can be lowered similarly to the first embodiment, and as a result, the out-heater 107 can be made long-lived, and the temperature of the wafer 40 can be made uniform. Thereby, the in-heater 108 and the out-heater 107 can be disposed in substantially the same plane, and a small apparatus in which the thickness of the height direction of the apparatus is reduced can be realized.

The reduction of the temperature difference in the annular holder 52 and the effect of lowering of damaging risk are the same as described in the first embodiment.

As described above, the apparatus 1f for manufacturing an epitaxial wafer according to the sixth embodiment reduces the temperature difference in the wafer holder 50, and thereby, the stress is relaxed to lower damaging risk or strain of the wafer holder 50, and also, by lowering the temperature of the out-heater 107, the out-heater 107 can be made long-lived, and temperature uniformity of the wafer 40 can be enhanced. Thus, this can provide the manufacturing apparatus and the manufacturing method of an epitaxial wafer with high productivity by which a uniform epitaxial film can be obtained.

### Seventh Embodiment

Next, a method for manufacturing an epitaxial wafer according to a seventh embodiment of the invention will be described.

FIG. 10 is a flow chart illustrating the method for manufacturing an epitaxial wafer according to the seventh embodiment of the invention.

As shown in FIG. 10, in the method for manufacturing an epitaxial wafer according to the seventh embodiment of the invention, first, a wafer 40 made of, for example, silicon is placed on the wafer holder 50 disposed on an upper portion of the rotator unit 70 provided inside the chamber 10 (Step S110). In this case, as the wafer holder 50, various ones described in the first to sixth embodiments can be used.

Next, the wafer 40 is heated by the inner heater 100 provided inside the rotator unit 70 and the outer heater 120 provided between the rotator unit 70 and the inner wall 12 of the chamber 10 (Step S120). In this case, as the inner heater 100 or the outer heater 120, various ones described in the first to sixth embodiments can be used.

Next, the reaction gas is introduced into the chamber 10 (Step S130). For example, as the reaction gas, a mixed gas of SiH₂Cl₂, which is a source gas, and H₂, which is a carrier gas, or the like can be used.

Next, while rotating the wafer 40 by the rotator unit 70, an epitaxial film is formed on the wafer 40 (Step S140).

As described above, in the method for manufacturing an epitaxial wafer according to the seventh embodiment, because heating is performed by the outer heater 120 in addition to the inner heater 100, the temperature difference in the wafer holder 50 can be reduced to relax the stress and thereby the damaging or strain of the wafer holder 50 can be prevented, and also, the temperature of the out-heater 102, 107 can be lowered to make the out-heater 102, 107 long-lived, and furthermore, the temperature uniformity of the wafer 40 can be improved, and the epitaxial wafer having a uniform epitaxial film can be obtained with good productivity.

The source gas is attached to the outer heater 120. When the fouling is removed by introducing a gas such as HCl, the outer heater 120 can be heated, thus the removal can be easily performed, and the embodiment of the invention is also excellent in the point of efficiency of cleaning of the apparatus.

In the above various embodiments, as the reaction gas, various silicon compounds can be used as well as SiCl₄, SiHCl₃, SiH₂Cl₂, SiH₃Cl, SiH₄, and so forth. Furthermore, when layers of single crystal silicon are grown one by one by alternately introducing the source gas and the gas such as H₂ or HCl, the invention can also be applied. Moreover, as the dopant, a gas of a boron compound such as diboran B₂H₆ or a phosphorous compound such as PH₃ may be mixed. By the manufacturing apparatus and the manufacturing method for the epitaxial wafer of this embodiment, the epitaxial wafer of high quality can be obtained stably, and quality of the semiconductor devices such as ultra-high speed bipolar and ultra-high speed CMOS is improved, and the production cost can be reduced.

Moreover, in the above embodiments, the case of epitaxially growing the single crystal film of silicon has been illustrated, but the invention is not limited thereto and other cases are possible. For example, the invention can be applied to the epitaxial growth of, for example, silicon carbide (SiC). In this case, as the gas to be used, the Si source can include SiH₄, and the C source can include C₃H₈, and the carrier gas can include H₂. Moreover, the n-type dopant gas can include N₂ and the p-type dopant gas can include Al(CH₃)₃.

On the other hand, in the invention, in addition to silicon carbide, thin films of various compounds can be formed. For example, on a substrate made of III-V group compound semiconductor or sapphire or the like, III-V group compound semiconductor or other various compounds can be formed. In this case, the compound to be formed is not limited to semiconductor, and an insulating body or a dielectric body is possible.

Specifically, for example, the embodiment of the invention can be applied to the case of epitaxially growing films of a gallium arsenide (GaAs) used for a constituent material of a Schottky diode for ultra-high frequency wave or microwave or a heterojunction bipolar transistor or a visible-light semiconductor laser. In this case, the gas to be used includes organic metals such as trimethyl gallium and triethyl gallium. Moreover, various dopant gases can be used.

The manufacturing apparatus and the manufacturing method for the epitaxial wafer described as the embodiment of the invention can be applied to the various manufacturing apparatuses and the various manufacturing methods for epitaxial wafers such as low-pressure CVD or normal-pressure CVD.

Moreover, in the embodiment of the invention, the cases where the wafer holder 50 is the annular holder 52 and the disc-like susceptor 54 are illustrated, but the invention is not limited thereto, and the wafer holders 50 having various shapes such as a structure having a projection part can be used.

Moreover, for the inner heater 100, in addition to the annular shape or the disc shape described above, the inner heaters having various shapes such as a radial pattern can be used.

In this specification, “disc-like” and “annular” represents the rough shape, and includes various modified shapes.

As described above, the embodiments of the invention has been described with reference to specific examples. However, the invention is not limited to the specific examples. For example, the specific configuration of each of the components constituting the manufacturing apparatus or the manufacturing method for an epitaxial wafer is included in the scope of the invention, as long as the invention can be carried out by appropriate selection from the known range by those skilled in the art and the same effect can be obtained.

Moreover, combination of two or more components of the respective specific examples in the technically possible range is included in the scope of the invention as long as including the spirit of the invention.

In addition, all of the manufacturing apparatuses and the manufacturing methods for epitaxial wafers that can be carried out with appropriately design-modified by those skilled in the art on the basis of the manufacturing apparatuses and the manufacturing methods for epitaxial wafers described above as the embodiments of the invention belong to the scope of the invention as long as including the spirit of the invention.

In addition, various variations and modifications can be conceived by those skilled in the art and it is understood that such variations and modifications belong to the scope of the invention as long as they fall within the spirit of the invention.

1. An apparatus for manufacturing an epitaxial wafer, comprising:
a chamber;
a gas inlet provided in the chamber and introducing a reaction gas into the chamber;
a gas outlet provided in the chamber and exhausting the reaction gas;
a rotator unit provided inside the chamber;
a wafer holder provided on an upper portion of the rotator unit and holding a wafer;
an inner heater provided inside the rotator unit; and
an outer heater provided between the rotator unit and an inner wall of the chamber.

2. The apparatus according to claim 1, wherein the wafer holder is an annular holder with an annular shape holding a peripheral portion of the wafer.

3. The apparatus according to claim 1, wherein the wafer holder is a susceptor holding a back surface of the wafer.

4. The apparatus according to claim 1, wherein the inner heater includes a disc-like in-heater and an annular out-heater provided in a peripheral portion of the in-heater.

5. The apparatus according to claim 4, wherein the out-heater is provided on a side of the wafer holder of the in-heater.

6. The apparatus according to claim 1, further comprising a shielding plate provided below the inner heater inside the rotator unit.

7. A method for manufacturing an epitaxial wafer, comprising:
placing a wafer on a wafer holder disposed on an upper portion of a rotator unit provided inside a chamber;
heating the wafer by an inner-heater provided inside the rotator unit and an outer-heater provided between the rotator unit and an inner wall of the chamber;
introducing a reaction gas into the chamber; and
forming an epitaxial film on the wafer while rotating the wafer by the rotator unit.
